(19) United States
(12) Patent Application Publication
(10) Pub. No.: US 2010/0288327 A1
(43) Pub. Date: Nov. 18, 2010

(54) System and method for over-Voltage protection of a photovoltaic string with distributed maximum power point tracking

(75) Inventors: Gianpaolo Lisi, Campbell, CA (US); Ali Djabbari, Saratoga, CA (US); Jianhui Zhang, San Jose, CA (US)

Correspondence Address: Munck Carter/NSC, P.O. Drawer 800889, Dallas, TX, 75380, US

(73) Assignee: National Semiconductor Corporation, Santa Clara, CA (US)

(21) Appl. No.: 12/454,136

(22) Filed: May 13, 2009

(51) Int. Cl. H01L 31/042

(52) U.S. Cl. 136/244

(57) ABSTRACT

A string over-voltage protection system and method for arrays of photovoltaic panels. The system and method includes a device for use in a photovoltaic array power system. The device includes a voltage converter. The voltage converter is adapted to be coupled to a photovoltaic panel in a string of photovoltaic panels. The device also includes a string over-voltage protection circuit. The string over-voltage protection circuit is coupled to the voltage converter. The string over-voltage protection circuit senses a string voltage and determines if a string over-voltage condition exists. Additionally, the string over-voltage protection circuit is configured to disable the voltage converter in the event of a string over-voltage condition.

### TECHNICAL FIELD OF THE INVENTION

The present application relates generally to electrical power systems and, more specifically, to a system and method for over-voltage protection in a solar-cell power system.

### BACKGROUND OF THE INVENTION

Photovoltaic (PV) panels (herein also referred to as solar panels) use radiant light from the sun to produce electrical energy. The solar panels include a number of PV cells to convert the sunlight into the electrical energy. The majority of solar panels use wafer-based crystalline silicon cells or a thin-film cell based on cadmium telluride or silicon. Crystalline silicon, which is commonly used in the wafer form in PV cells, is derived from silicon, a commonly used semi-conductor. PV cells are semiconductor devices that convert light directly into energy. When light shines on a PV cell, a voltage develops across the cell, and when connected to a load, a current flows through the cell. The voltage and current vary with several factors, including the physical size of the cell, the amount of light shining on the cell, the temperature of the cell, and external factors.

A solar panel (also referred to as PV module) is made of PV cells arranged in series and parallel. For example, the PV cells are first coupled in series within a string. Then, a number of strings are coupled together in parallel. Likewise a PV array (also referred to as solar array) is made of solar panels arranged in series and in parallel.

The electrical power generated by each solar panel is determined by the solar panel's voltage and current. In a solar array electrical connections are made in series to achieve a desired output string voltage and/or in parallel to provide a desired amount of string current source capability. In some cases, each panel voltage is boosted or bucked with a DC-DC converter.

The solar array is connected to an electrical load, an electrical grid or an electrical power storage device, such as, but not limited to, battery cells. The solar panels delivery Direct Current (DC) electrical power. When the electrical load, electrical grid or electrical power storage device operates using an Alternating Current (AC), (for example, sixty cycles per second or 60 Herz (Hz)), the solar array is connected to the electrical load, electrical grid, or electrical power storage device, through a DC-AC inverter.

Solar panels exhibit voltage and current characteristics described by their I-V curve, an example of which is shown in FIG. 1. When the solar cells are not connected to a load, the voltage across their terminals is their open circuit voltage, V_{oc}. When the terminals are connected together to form a short circuit, a short circuit current, I_{sc}, is generated. In both cases, since power is given by voltage multiplied by current, no power is generated. A Maximum Power Point (MPP) defines a point wherein the solar panels are operating at their maximum power.

Often a solar panel is capable of large and fast power transients. During these transients, the difference between the power generated by the solar panel and the power put on the grid by the inverter (e.g., in the case of a solar array connected to the grid) is stored and released by an electrical energy storage device (e.g., an inverter input capacitor). Under certain conditions, referred to hereinafter as a string overvoltage, the power difference can cause the inverter input voltage to exceed the inverter's maximum rating causing severe and permanent damage to the inverter.

### SUMMARY OF THE INVENTION

A solar panel array for use in a solar cell power system is provided. The solar panel array includes a number of strings of solar panels and a number of voltage converters. Each of the voltage converters is coupled to a corresponding solar panel in the string of solar panels. Additionally, the solar panel array includes a number of over-voltage protection circuits. Each of the over-voltage protection circuits is coupled to a corresponding voltage converter. Each of the over-voltage protection circuits is configured to control an operation of the voltage converter in response to a string over-voltage condition.

A device for use in a solar cell power system is provided. The device includes a voltage converter. The voltage converter is adapted to be coupled to a solar panel in a string of solar panels. The device also includes an over-voltage protection circuit. The over-voltage protection circuit is coupled to the voltage converter. Additionally, the over-voltage protection circuit is configured to control an operation of the voltage converter in response to a string over-voltage condition.

A method for over-voltage avoidance in a photovoltaic array is provided. The method includes sensing a string voltage at a solar panel in a string of solar panels. The method further includes determining if the string voltage exceeds a threshold voltage and controlling an operation of a voltage converter coupled to the solar panel.

Before undertaking the DETAILED DESCRIPTION OF THE INVENTION below, it may be advantageous to set forth definitions of certain words and phrases used throughout this patent document. The term “packet” refers to any information-bearing communication signal, regardless of the format used for a particular communication signal. The terms “application,” “program,” and “routine” refer to one or more computer programs, sets of instructions, procedures, functions, objects, classes, instances, or related data adapted for implementation in a suitable computer language. The term “couple” and its derivatives refer to any direct or indirect communication between two or more elements, whether or not those elements are in physical contact with one another. The terms “transmit,” “receive,” and “communicate,” as well as derivatives thereof, encompass both direct and indirect communication. The terms “include” and “comprise,” as well as derivatives thereof, mean inclusion without limitation. The term “or” is inclusive, meaning and/or. The phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. The term “controller” means any device, system, or part thereof that controls at least one operation. A controller may be implemented in hardware, firmware, software, or some combination of at least two of the same. The functionality associated with any particular controller may be centralized or distributed, whether locally or remotely.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates an example I-V curve for a photovoltaic panel;

FIG. 2 illustrates a PV array system according to embodiments of the present disclosure;

FIG. 3 illustrates an example solar panel according to embodiments of the present disclosure;

FIG. 4 illustrates an example solar panel string 210 according to embodiments of the present disclosure;

FIG. 5 illustrates an example solar panel string 210 with a panel string over-voltage protection circuit according to embodiments of the present disclosure;

FIG. 6 illustrates another example solar panel string 210 with a panel string over-voltage protection circuit according to embodiments of the present disclosure; and

FIG. 7 illustrates an over-voltage protection process in a PV array according to embodiments of the present disclosure.

### DETAILED DESCRIPTION OF THE INVENTION

FIGS. 2 through 7, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged photovoltaic array system.

FIG. 2 illustrates a PV array system according to embodiments of the present disclosure. The embodiment of the PV array system 200 shown in FIG. 2 is for illustration only. Other embodiments of the PV array system 200 could be used without departing from the scope of this disclosure.

The PV array system 200 includes a number of solar panels 205. The solar panels 205 are arranged in series, in parallel, or both. For example, solar panel 205-1a can be coupled in series with solar panel 205-1b while solar panel 205-2a is coupled in series with solar panel 205-2b. Additionally, solar panels 205-1a and 205-1b are coupled in parallel with solar panels 205-2a and 205-2b. Solar panels 205 coupled in series (e.g., solar panels 205-1a and 205-1b) are referred to as strings. Therefore, as shown in FIG. 2, solar panels 205-1a and 205-1b form a first string 210-1 and solar panels 205-2a and 205-2b form a second string 210-2. Further, the voltage across the string 210 is referred to as the string voltage and the current through the string 210 is the string current. It will be understood that illustration of two solar panels 205 per string 210 and two strings 210 in the PV array 200 is for example purpose only and embodiments with more than two solar panels per string and more than two strings per PV array could be used without departing from the scope of this disclosure.

The PV array system 200 includes a DC-AC inverter 235. The PV array system 200 (e.g., solar array) is coupled to the DC-AC inverter 235. The solar panels 205 can be coupled in series with one or more additional solar panels 205 to the DC-AC inverter 235. Additionally and alternatively, the solar panels 205 can be coupled in parallel with one or more additional solar panels 205 to the DC-AC inverter 235. The DC-AC inverter 235 extracts power from the PV array 200 and converts the extracted power from DC to AC for interconnection with a power distribution grid (hereinafter “grid”) 240.

Each string 210 of the PV array 200 is sized according to a specified size for operation with the DC-AC inverter 235. The specified size is determined such that the sum of the open-circuit voltage of all the solar panels 205 in a string 210 cannot exceed a maximum DC-AC inverter 235 input voltage rating corresponding to the temperature conditions specified by the PV array application.

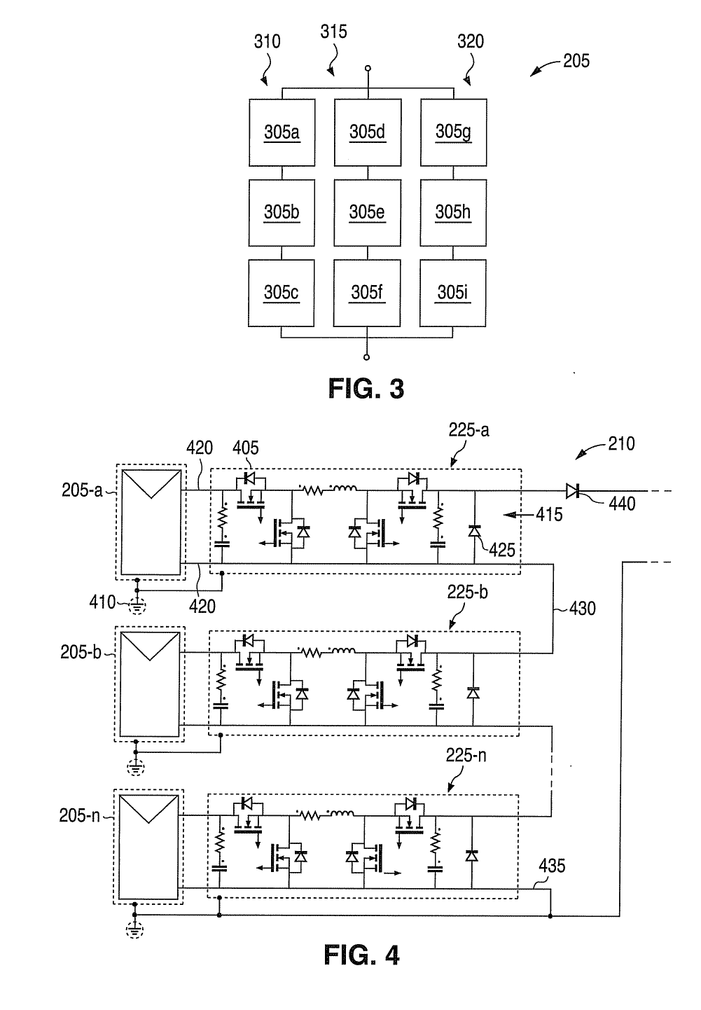

FIG. 3 illustrates an example solar panel according to embodiments of the present disclosure. The embodiment of the solar panel 205 shown in FIG. 3 is for illustration only. Other embodiments of the solar panel 205 could be used without departing from the scope of this disclosure.

Each solar panel 205 includes a number of PV cells 305 arranged in series, in parallel, or both. For example, a first string 310 of PV cells is formed when PV cells 305a, 305b and 305c are coupled in series. A second string 315 of PV cells is formed when PV cells 305d, 305e and 305f are coupled in series. A third string 320 of PV cells is formed when PV cells 305g, 305h and 305i are coupled in series. Thereafter, the first string 310, second string 315 and third string 320 are coupled in parallel to form the solar panel 205.

The PV cells are semiconductor devices that convert light directly into energy. When light shines on a PV cell, a voltage develops across the cell, and when connected to a load, a current flows through the cell. The voltage and current vary with several factors, including the physical size of the cell, the amount of light shining on the cell, the temperature of the cell, and external factors. The PV cells are coupled together such that each solar panel exhibits a positive potential (e.g., voltage).

Each solar panel 205 is coupled on its output terminals to a Panel Dedicated Converter (PDC) 220. The PDC includes a DC-DC converter 225 coupled to the solar panel 205. Accordingly, the voltage across DC-DC converters 225 coupled in series is the string voltage and the current through the DC-DC converters 225 coupled in series is the string current. The DC-DC converter 225 is configured to provide power conversion (e.g., bucking and boosting) for the solar panel 205. The DC-DC converter 225 converts the power to a voltage or current level which is more suitable to whatever load the system is designed to drive. For example and not limitation, the DC-DC converter 225 can perform two to one (2:1) boosting of the voltage received from the solar panel 205. In such example, the solar panel 205 is configured to output voltage in a range of one volt (1V) to fifty volts (50V) (e.g., output voltage may depend on amount of sunlight received at the solar panel 205). The DC-DC converter 225 is capable of converting its input voltage into an output voltage ranging from one volt (1V) to hundred volts (100V) (e.g., when a high-voltage converter). In an additional example, the solar panel is configured to output voltage in a range of one volt (1V) to thirty volts (30V). The DC-DC converter 225 is capable of converting its input voltage into an output voltage ranging from one volt (1V) to fifty volts (50V) (e.g., when a low-voltage converter). It will be understood that the DC-DC converter 225 can perform buck as well as boost or buck-boost operation.

The PDC 220 includes a Maximum Power Point Tracking (MPPT) controller 230 coupled to the DC-DC converter 225. The MPPT controller 230 also is configured to sense the voltage and current from each solar panel 205. The MPPT controller 230 includes a central processing unit (“CPU”), a memory unit, an input/output (“I/O”) device, one or more interfaces configured to couple to the DC-DC converter, and one or more sensory input terminals (“sensors”) configured to measure current and voltage at the input and output of the DC-DC converter 225. The CPU, memory, I/O device, interfaces, and sensors are interconnected by one or more communication links (e.g., a bus). It is understood that the MPPT controller 230 may be differently configured and that each of the listed components may actually represent several different components. For example, the CPU may actually represent a multi-processor or a distributed processing system; the memory unit may include different levels of cache memory, main memory, hard disks, and remote storage locations; and the I/O device may include monitors, keyboards, and the like. Additionally, the memory unit stores a plurality of instructions configured to cause the CPU to perform one or more of the functions of the MPPT controller 230 outlined herein below. The memory unit also is capable of storing one or more sensed values received via sensors and/or interfaces. Additionally, the memory unit is capable of storing threshold values.

PV cells have a single operating point, referred to as the Maximum Power Point (MPP) 105, where the values of the current (I) and Voltage (V) of the cell result in maximum power output. A PV cell has an exponential relationship between current and voltage, and the maximum power point (MPP) 105 occurs at the knee of the curve where the resistance is equal to the negative of the differential resistance (V/I=−ΔV/ΔI). The MPPT controller 230 searches for the MPP 105. Then, the MPPT controller 230 varies the duty cycle of the DC-DC converter 225. Therefore, the MPPT controller 230 enables the DC-DC converter 225 to extract the maximum power available from the PV module 305.

Therefore, the PDC 220 is a high efficiency DC to DC converter that functions as an optimal electrical load for the solar panel 205 (or PV array 200 when coupled to the entire array), and converts the power to a voltage or current level that is more suitable to whatever load the system is designed to drive. The PDC 220 is capable of performing per panel maximum power point tracking.

A solar panel 205 operated at the MPP can be modeled at steady-state as an ideal power source as described, using generator convention, by Equation 1:

Vₚₐₙ(t)*Iₚₐₙ(t)=P_{MPP}. [Eqn. 1]

In Equation 1, Vₚₐₙ(t) is the solar panel 205 voltage, Iₚₐₙ(t) is the solar panel 205 current, and P_{MPP} is the power generated at the solar panel 205 at MPP.

The grid-tied DC-AC inverter 235 can be modeled at steady-state as an ideal power sink, described using load convention by Equation 2:

V_{string}(t)*I_{string}(t)=P_{string}. [Eqn. 2]

In Equation 2, V_{string}(t) is the input voltage of the DC-AC Inverter 235, I_{string}(t) is the input current of the DC-AC Inverter 235, and P_{string} is the total input power.

The total power generated by the PV array 200 is the input power of the DC-AC inverter 235. At steady-state, the input power generated by the PV array 200 equals the power put in the distribution grid 240 by the DC-AC inverter 235. Steady-state neat power balance is achieved by an active controller (not shown) integrated in the DC-AC inverter 235. To assist in achieving instantaneous power balance during transients, the DC-AC inverter 235 also includes an energy storage component (not shown). The energy storage component can be, but is not limited to, a capacitor connected at the input terminals of the DC-AC inverter 235.

The PV array 200 is capable of large and fast power transients. During these transients, a difference between the power generated by the PV array 200 and the power output to the grid 240 by the DC-AC inverter 235 is stored and released by the inverter capacitor. String overvoltage a sudden variation of the operating conditions of the PV array or of the DC-AC inverter causes a significant unbalance between the power generated by the PV array and the power put on the distribution grid by the DC-AC inverter. In such a condition the string voltage can exceed the maximum input voltage rating of the DC-AC inverter 235. Additionally, string overvoltage can occur as a result of a sudden AC-side disconnect at the DC-AC inverter 235, while the PV array is operated under MPPT. In such condition, since PDC 220 performs real-time MPPT of the solar panel 205 to which the PDC 220 is connected, the power generated by the PV array 200 can be considered constant while the power output on the grid 240 by the DC-AC inverter 235 drops suddenly to zero. Accordingly, the entire power from the PV array 200 is transferred to the inverter input capacitor as defined by Equations 3 and 4:

$$\begin{matrix}{V}_{string} ( t ) * {I}_{string} ( t ) = {P}_{array} . & [ Eqn . 3 ] \\ {I}_{string} ( t ) = C \frac{d {V}_{string} ( t )}{d t} & [ Eqn . 4 ]\end{matrix}$$

In Equations 3 and 4, C is the capacitance of the inverter input capacitor and P_{array} is the total power generated by the PV array 200. Equations 3 and 4 can be rewritten as Equation 5:

$${V}_{string} ( t ) = \sqrt{\frac{2 {tP}_{array}}{C}} . \qquad [ Eqn . 5 ]$$

Equation 5 illustrates that the string voltage will grow indefinitely.

FIG. 4 illustrates an example solar panel string 210 according to embodiments of the present disclosure. The embodiment of the string 210 shown in FIG. 4 is for illustration only. Other embodiments of the string 210 could be used without departing from the scope of this disclosure.

As stated herein above with respect to FIG. 2, each solar panel 205 is coupled to a DC-DC converter 225. The DC-DC converter 225 can be included in the PDC 220 with the MPPT controller 230. In additional and alternative embodiments, the DC-DC converter 225 is not contained in the PDC 220; rather, the DC-DC converter 225 is a self-contained device with an external MPPT controller 230 coupled thereto.

For example, one or more DC-DC converters 225 include a housing 405. The housing 405 may be constituted of conductive material or just include a galvanic connection between a point inside the housing itself and ground 410. The housing 405 contains the DC-DC converter circuitry 415 and may or may not contain the MPPT controller 230. The DC-DC converter circuitry 415 couples to the solar panel 205 terminals via input terminals 420. A bypass diode 425 (also referred to as an output diode) is coupled between the output terminals of each DC-DC converter 225. The solar panels 205 are coupled in series such that a negative output terminal of a first solar panel 205-a is coupled 430 to a positive output terminal of a second solar panel 205-b; and so forth. Each solar panel 205 is coupled to a next solar panel 205 in such manner in series through to a last solar panel 205-n. The negative output terminal 435 of the last solar panel 205-n also is coupled to ground 410. Further, the first DC-DC converter 225a is coupled to the DC-AC inverter 235 through a blocking diode 440.

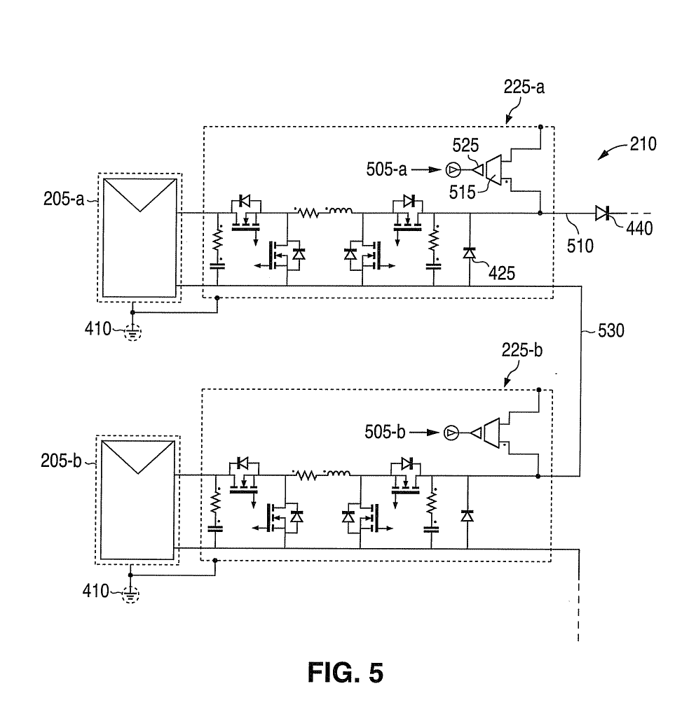

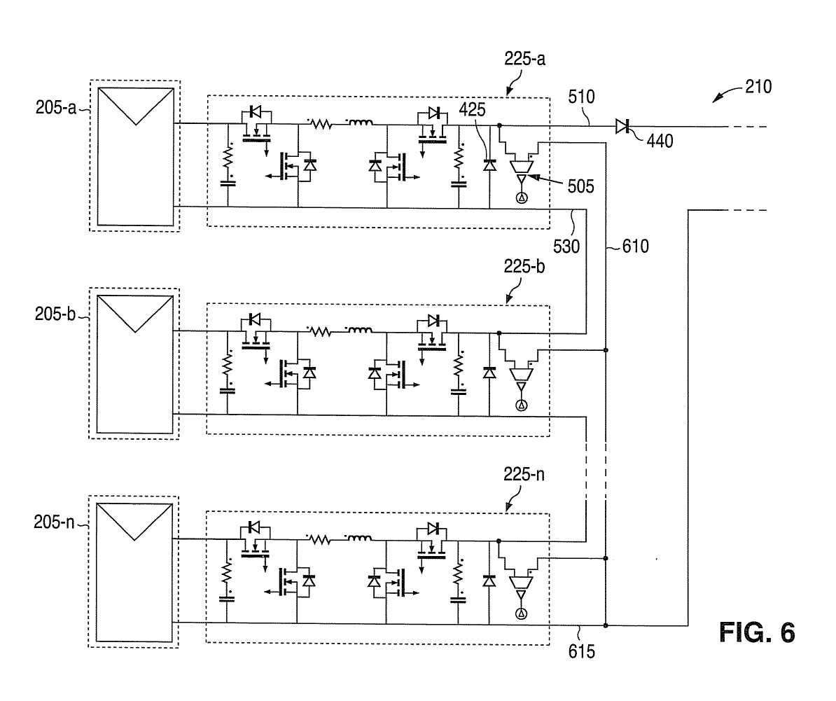

FIG. 5 illustrates an example solar panel string 210 with a Panel String Over-Voltage Protection Circuit (PSOVPC) according to embodiments of the present disclosure. The embodiment of the string 210 shown in FIG. 5 is for illustration only. Other embodiments of the string 210 could be used without departing from the scope of this disclosure.

In some embodiments, one or more DC-DC controllers 225 includes a PSOVPC 505. The PSOVPC 505 is coupled between a positive output terminal 510 of the DC-DC converter circuitry 415 and the housing 405. The PSOVPC 505 includes a sensor 515 configured to detect a voltage difference between the housing 405 and the positive output terminal 510. Further, the positive output terminal 510 of the first DC-DC converter 225a is coupled to the DC-AC inverter 235 through the blocking diode 440. For example, the sensor 515 can be a device configured to detect and measure voltage such as, but not limited to, a volt-meter. The PSOVPC 505 includes a controller 525 and memory (not specifically illustrated). The PSOVPC 505 is coupled to control elements (e.g. switches) in the DC-DC converter circuitry 415. Accordingly, the PSOVPC 505 is operable to switch the DC-DC converter 225 ON and OFF. In some embodiments, the PSOVPC 505 controller 525 is integrated with the DC-DC converter circuitry 415 such that the DC-DC converter circuitry 415 receives voltage measurements from the sensor 515 and operates the switches coupled to the bucking and boosting elements of the DC-DC converter circuitry 415 to switch ON and OFF.

In one example and not limitation, each solar panel 205 is configured to generate fifty volts (50V). In a string 210 of four (4) solar panels 205, each string 210 has a maximum string voltage of two hundred volts (200V). Since each solar panel 205 is coupled to a corresponding DC-DC converter 225, the output of each solar panel 205 can be as high as one hundred volts (100V). Therefore, the maximum string voltage is four hundred volts (400V). This voltage may exceed the maximum input voltage rating of the DC-AC inverter 235.

The PSOVPC 505 includes a threshold value stored in memory. The threshold value corresponds to a voltage level at which the controller 525 will disable (e.g., switch OFF) the DC-DC converter 225. Alternatively, in one embodiment of the present disclosure, the controller 525 can limit the output voltage of the converter 225 to an arbitrary value.

In order to avoid string over-voltage, the PSOVPC 505 senses the voltage difference between the housing 405 and the positive output terminal 510. For example, since the housing 405 of each solar panel 205 is coupled to ground 410 as well as the negative output terminal of the last solar panel 205-n, the voltage difference between the positive output terminal 510 of the DC-DC converter 225 coupled to the first solar panel 205-a and the DC-DC converter 225 housing 405 is the string 210 voltage. Therefore, the PSOVPC 505-a in the DC-DC converter 225-a coupled to the first solar panel 205-a senses the voltage across the string 210.

When a string over-voltage occurs, the PSOVPC 505-a in the DC-DC converter 225-a (hereinafter also referred to as the first PSOVPC 505-a for clarity in the following examples) coupled to the first solar panel-la senses the over-voltage first. Accordingly, the DC-DC converter 225-a coupled to the first solar panel 205-a will be disabled.

For example, the threshold value in each PSOVPC 505 may be set to three hundred volts (300V). When the string voltage is two-hundred ninety-nine volts (299V), the first PSOVPC 505-a detects that the sting voltage is less than the threshold. The controller 525 in the first PSOVPC 505-a compares the sensed voltage (e.g., 299V) with the threshold voltage (e.g. 300V). Additionally, since the solar panels 205 are coupled in series, each other PSOVPC 505 detects less than the string voltage, therefore the PSOVPC 505 coupled to the first DC-DC converter 225-a (e.g. the first PSOVPC 505-a) is the first to detect a string over-voltage condition.

Since the string voltage is less than the threshold voltage, the controller 525 in the first PSOVPC 505-a continues to monitor (e.g. sense) the voltage. However, if the string voltage increases such that the string voltage exceeds the threshold, the first PSOVPC 505-a detects that a string over-voltage condition exists and disables the DC-DC converter 225-a. When the string voltage exceeds the threshold voltage, the controller 525 in the first PSOVPC 505 instructs the DC-DC converter circuitry 415 (e.g., sends commands to one or more switching devices included in the DC-DC converter circuitry 415) to switch OFF (i.e., disables the DC-DC converter 225). When the DC-DC converter 225 is disabled, the string current flows from the negative output terminal 530 through the bypass diode 425 to the positive output terminal 510 and, then through the blocking diode 410 to the DC-AC inverter 235 (illustrated on FIG. 2).

Thereafter, the voltage difference between the positive output terminal (e.g., the positive output terminal of DC-DC converter 225-b coupled to the negative output terminal 530 of DC-DC converter 225-a) of the DC-DC converter 225-b coupled to the second solar panel 205-b and the DC-DC converter 225 housing 405 is the string 210 voltage. Therefore, the PSOVPC 505-b in the DC-DC converter 225-b coupled to the second solar panel 205-b senses the string voltage. If a string over-voltage condition still exists, the PSOVPC 505-b disables the DC-DC converter 225-b. Each successive PSOVPC 505 will disable a corresponding DC-DC converter 225 until the string voltage is below the threshold voltage.

FIG. 6 illustrates another example solar panel string 210 with a Panel String Over-Voltage Protection Circuit according to embodiments of the present disclosure. The embodiment of the string 210 shown in FIG. 6 is for illustration only. Other embodiments of the string 210 could be used without departing from the scope of this disclosure.

In some embodiments, the housings 405 for each of the DC-DC converters 225 are not coupled to ground 410. Further, one or more DC-DC converters 225 includes the PSOVPC 505. In such embodiments, a bus 610 is coupled from the negative output terminal 615 of the last DC-DC converter 225 to each of the PSOVPC's 505. Accordingly, for each DC-DC converter 225, the PSOVPC 505 is coupled between the positive output terminal 510 of the DC-DC converter circuitry 415 and the bus 610 to the negative output terminal of converter 225-n.

As before, the PSOVPC 505 includes a sensor 515 configured to detect a voltage difference between the positive output terminal 510 and the bus 610. For example, the sensor 515 can be a device configured to detect and measure voltage such as, but not limited to, a volt-meter. The PSOVPC 505 includes the controller 525 and memory (not specifically illustrated). The PSOVPC 505 is coupled to control elements (e.g. switches) in the DC-DC converter circuitry 415. Accordingly, the PSOVPC 505 is operable to switch the DC-DC converter 225 ON and OFF. In some embodiments, the PSOVPC 505 controller 525 is integrated with the DC-DC converter circuitry 415 such that the DC-DC converter circuitry 415 receives voltage measurements from the sensor 515 and operates the switches coupled to the bucking and boosting elements of the DC-DC converter circuitry 415 to switch ON and OFF.

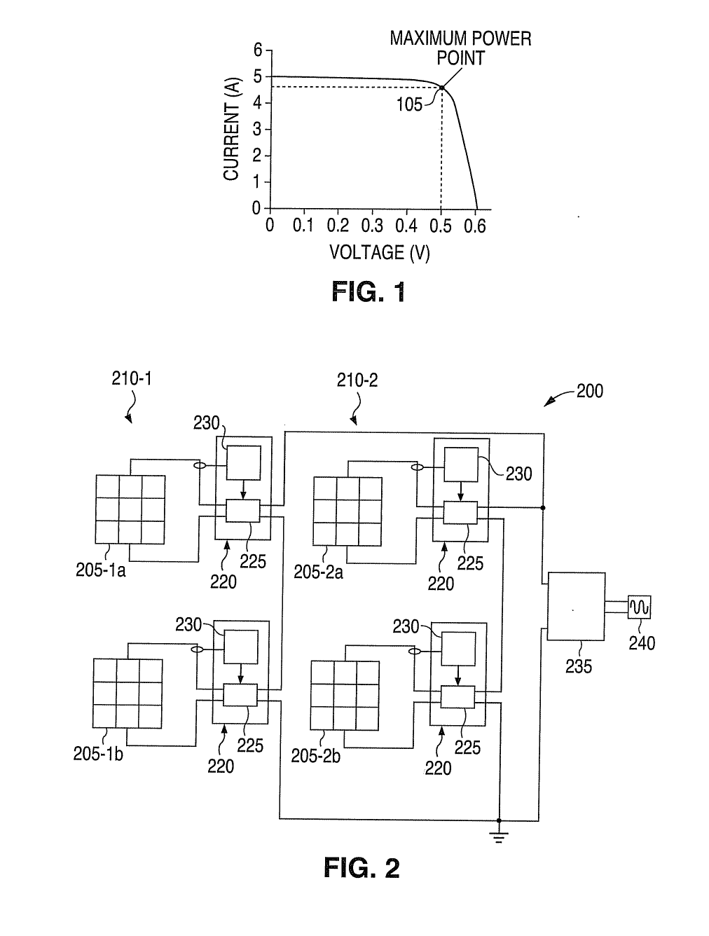

In one example and not limitation, each solar panel 205 is configured to generate up to fifty volts (50V). In a string of four (4) solar panels 205, each string 210 has a maximum string voltage of two hundred volts (200V). Since each solar panel 205 is coupled to a corresponding DC-DC converter 225, the output of each solar panel 205 can be as high as one hundred volts (100V). Therefore, the maximum string voltage is four hundred volts (400V). This voltage may exceed the maximum voltage for the DC-AC inverter 235 (illustrated in FIG. 1).

The PSOVPC 505 includes a threshold value which can be stored in memory or, for other embodiments of the present disclosure, determined dynamically. The threshold value corresponds to a voltage level at which the controller 525 will disable (e.g., switch OFF) the DC-DC converter 225. For other embodiments of the current disclosure the controller 525 can limit the output voltage of converter 225 to a predetermined or calculated value once such a threshold is exceeded

In order to avoid string over-voltage, the PSOVPC 505 senses the voltage difference between the positive output terminal 510 and the bus 610. For example, since the bus 610 is coupled to the negative output terminal 615 of the last DC-DC converter 225-n coupled to the last solar panel 205-n, the voltage difference between the positive output terminal 510 of the DC-DC converter 225 coupled to the first solar panel 205-a and the bus 610 is the string 210 voltage. Therefore, the PSOVPC 505-a in the DC-DC converter 225-a coupled to the first solar panel 205-a senses the voltage across the string 210.

When a string over-voltage occurs, the first PSOVPC 505-a in the DC-DC converter 225-a coupled to the first solar panel-1a senses the over-voltage first. Accordingly, the DC-DC converter 225-a coupled to the first solar panel 205-a is disabled by the first PSOVPC 505-a.

For example, the threshold value in each PSOVPC 505 may be set to three hundred volts (300V). When the string voltage is two-hundred ninety-nine volts (299V), the first PSOVPC 505-a detects that the sting voltage is less than the threshold. Additionally, since the solar panels 205 are coupled in series, each other PSOVPC 505 detects less than the string voltage, therefore the PSOVPC 505 coupled to the first DC-DC converter 225-a (e.g. the first PSOVPC 505-a) is the first to detect a string over-voltage condition. The controller 525 in the first PSOVPC 505-a compares the sensed voltage (e.g., 299V) with the threshold voltage (e.g. 300V).

Since the string voltage is less than the threshold voltage, the controller 525 in the first PSOVPC 505-a continues to monitor (e.g. sense) the voltage. However, if the string voltage increases such that the string voltage exceeds the threshold, the first PSOVPC 505-a detects that a string over-voltage condition exists and disables the DC-DC converter 225-a. When the string voltage exceeds the threshold voltage, the controller 525 in the first PSOVPC 505 instructs the DC-DC converter circuitry 415 (e.g., sends commands to one or more switching devices included in the DC-DC converter circuitry 415) to switch OFF (i.e., disables the DC-DC converter 225). When the DC-DC converter 225 is disabled, the string current flows from the negative output terminal 530 through the bypass diode 425 to the positive output terminal 510 and, then through the blocking diode 440 to the DC-AC inverter 235 (illustrated on FIG. 2).

Thereafter, the voltage difference between the positive output terminal (e.g., the positive output terminal of DC-DC converter 225-b coupled to the negative output terminal 530 of DC-DC converter 225-a) of the DC-DC converter 225-b coupled to the second solar panel 205-b and the bus 610 is the string 210 voltage. Therefore, the PSOVPC 505-b in the DC-DC converter 225-b coupled to the second solar panel 205-b senses the string voltage. If a string over-voltage condition still exists, the PSOVPC 505-b disables the DC-DC converter 225-b. Each successive PSOVPC 505 will disable a corresponding DC-DC converter 225 until the string voltage is below the threshold voltage.

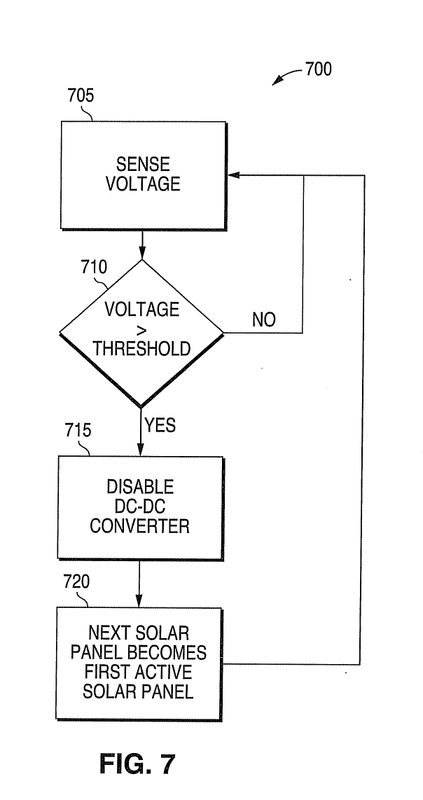

FIG. 7 illustrates an over-voltage protection process in a PV array according to embodiments of the present disclosure. The embodiment of the over-voltage protection process 700 shown in FIG. 7 is for illustration only. Other embodiments of the over-voltage protection process 700 could be used without departing from the scope of this disclosure.

The PV array 200 includes a number of solar panels 205. The solar panels 205 are coupled in series to form strings 210. The strings are coupled in series to form the PV array 200. In one embodiment of the present disclosure, the PV array 200 is coupled to an electrical load 240 (e.g., electrical distribution grid 240) via a DC-AC inverter 235. One or more arrays 200 may exist at one PV site.

Each solar panel 205 is coupled to a DC-DC converter 225. The DC-DC converter 225 may be included with a MPPT 230 within a PDC 220 or one or more DC-DC converters 225 may be self-contained and coupled to an external MPPT 230. Each DC-DC converter 225 also is coupled to a PSOVPC 505. The PSOVPC 505 may be external to the DC-DC converter 225, internal to the DC-DC converter 225 or contained within the MPPT 230. However, for the purposes of the following example, the PSOVPC 505 is illustrated as internal to the DC-DC converter 225. It will be understood that embodiments wherein the PSOVPC 505 is a unit external to the DC-DC converter 225 or included as part of the MPPT 230 apply equally.

During operation, each PSOVPC 505 senses the voltage across its terminals in step 705. However, the PSOVPC 505 in the DC-DC converter 225 coupled to the first active solar panel 205 senses the voltage across the string 210 (also referred to as the string voltage). The first active solar panel 205 is the solar panel 205 coupled to an enabled (e.g., ON) DC-DC converter such that the output via positive output terminal of the DC-DC converter 225 is received at the input of the DC-AC inverter 235. For example, the first solar panel 205 in the string 210 is the solar panel that is coupled between the remaining solar panels and a positive input of the DC-AC inverter. The second solar panel 205 is the solar panel 205 that is coupled between the first solar panel 205 and the third solar panel 205, and so forth. The last solar panel 205 is the solar panel 205 coupled between the negative input of the DC-AC inverter 235 and the remaining solar panels 205. At steady state, when all the DC-DC converters 225 are active, the first active solar panel 205 is the first in the series. However, if the DC-DC converter 225 coupled to the first solar panel 205 is disabled, then the second solar panel 250 in the series (e.g., string 210) becomes the first active solar panel 205 (assuming the DC-DC converter 225 coupled to the second solar panel 205 is active).

The PSOVPC 505 compares the sensed voltage with a threshold voltage value in step 710. Each PSOVPC 505 compares its sensed voltage against the threshold voltage value. However, the PSOVPC 505 in the DC-DC converter 225 coupled to the first active solar panel 205 senses the largest voltage value (e.g., the PSOVPC 505 in the DC-DC converter 225 coupled to the first active solar panel 205 senses the string voltage 210).

If the PSOVPC 505 determines that the sensed voltage is less than or equal to the threshold voltage (sensed≦threshold), then the PSOVPC 505 does not alter, e.g., disable, the DC-DC converter 225 settings. In some embodiments, the PSOVPC 505 actives (e.g., turns ON) the DC-DC converter 225 if the DC-DC converter 225 previously was disabled (e.g., OFF). Thereafter, the process returns to step 705.

If the PSOVPC 505 determines that the sensed voltage exceeds the threshold voltage (sensed>threshold), then the PSOVPC 505 disables the DC-DC converter 225 in step 715. In some embodiments, the PSOVPC 505 sends a command to a controller in the DC-DC converter 225 to disable bucking or boosting of the voltage generated by the solar panel 205. In some embodiments, the PSOVPC 505 operates switches coupled to elements in the DC-DC converter 225 to terminate bucking or boosting of the voltage generated by the solar panel 205. In some embodiments, when the PSOVPC 505 disables a DC-DC converter 225, the string current is routed through a bypass diode 425 coupled between the output terminals of the DC-DC converter 225 such that the DC-DC converter 225 circuitry is bypassed.

When a DC-DC converter 225 is disabled by a respective PSOVPC 505, the solar panel 205 effectively is removed from contributing power (e.g., voltage and current) to the string 210. Therefore, the solar panel 205 is referred to as inactive and the next solar panel 205 in the string 210 becomes the first active solar panel 205 in step 720. Thereafter, the process returns to step 705 where this next solar panel 205 is the first active solar panel 205.

The over-voltage protection process 700 continues. Additional solar panels 205 are de-activated (e.g. by disabling the corresponding DC-DC converter 225) until the string voltage is less than or equal to the threshold voltage. In additional and alternative embodiments, the condition that caused the string over voltage to occur is corrected. Thereafter, solar panels 205 that were de-activated by the over-voltage protection process 700 are re-activated either systematically (e.g., progressively) or simultaneously.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. A solar panel array for use in a solar cell power system, the solar panel array comprising:
a number of strings of solar panels;
a number of voltage converters, wherein each of the voltage converters is coupled to a corresponding solar panel in the string of solar panels; and
a number of over-voltage protection circuits, wherein each of the over-voltage protection circuits is coupled to a corresponding voltage converter, each of the over-voltage protection circuits configured to control an operation of the voltage converter in response to a string over-voltage condition.

2. The solar panel array as set forth in claim 1, wherein each of the number of over-voltage protection circuits is configured to sense a voltage corresponding to a string voltage.

3. The solar panel array as set forth in claim 2, the voltage corresponding to the string voltage is a voltage between a positive output terminal and a housing of the voltage converter.

4. The solar panel array as set forth in claim 2, the voltage corresponding to the string voltage is a voltage between a positive output terminal of a first voltage converter and a negative output terminal of a second voltage converter.

5. The solar panel array as set forth in claim 1, wherein each of the number of over-voltage protection circuits includes at least one of a static threshold voltage value and dynamic threshold voltage value.

6. The solar panel array as set forth in claim 5, wherein at least one of the number of over-voltage protection circuits disables the voltage converter when a string voltage exceeds the threshold voltage.

7. The solar panel array as set forth in claim 1, wherein at least one of the number of over-voltage protection circuits controls operation of the voltage converter by at least one of:
switching OFF elements in the voltage converter;
limiting the output voltage of the voltage converter to a predetermined or calculated value; and
bypassing circuitry within the voltage converter.

8. A device for use in a solar cell power system, the device comprising:
a voltage converter, wherein the voltage converter is adapted to be coupled to a solar panel in a string of solar panels; and
an over-voltage protection circuit coupled to the voltage converter, the over-voltage protection circuit configured to control an operation of the voltage converter in response to a string over-voltage condition.

9. The device as set forth in claim 8, wherein the over-voltage protection circuit is configured to sense a voltage corresponding to a string voltage.

10. The device as set forth in claim 9, the voltage corresponding to the string voltage is a voltage between a positive output terminal and a housing of the voltage converter.

11. The device as set forth in claim 9, the voltage corresponding to the string voltage is a voltage between a positive output terminal of a first voltage converter and a negative output terminal of a second voltage converter.

12. The device as set forth in claim 8, wherein the over-voltage protection circuit includes at least one of a static threshold voltage value and dynamic threshold voltage value.

13. The device as set forth in claim 12, wherein the over-voltage protection circuit disables the voltage converter when a string voltage exceeds the threshold voltage.

14. The device as set forth in claim 8, wherein the over-voltage protection circuit controls operation of the voltage converter by at least one of:
switching OFF elements in the voltage converter;
limiting the output voltage of the voltage converter to a predetermined or calculated value; and
bypassing circuitry within the voltage converter.

15. A method for over-voltage protection in a photovoltaic array, the method comprising:
sensing a string voltage at a solar panel in a string of solar panels;
determining if the string voltage exceeds a threshold voltage; and
controlling and operation of a voltage converter coupled to the solar panel.

16. The method set forth in claim 15, wherein controlling disabling the voltage converter when the string voltage exceeds the threshold voltage.

17. The method as set forth in claim 16, wherein disabling further comprises at least one of:
switching OFF elements in the voltage converter;
limiting the voltage of the voltage converter to a predetermined or calculated value; and
bypassing circuitry within the voltage converter.

18. The method as set forth in claim 15, further comprising storing the threshold value in a memory.

19. The method as set forth in claim 15, wherein sensing further comprises sensing a voltage between a positive output terminal of the voltage converter and a housing of the voltage converter.

20. The method as set forth in claim 15, wherein sensing further comprises sensing a voltage between a positive output terminal of the voltage converter and a negative output terminal of a last voltage converter coupled to a last solar panel in the string of solar panels.
